(19) United States
(12) Patent Application Publication
(10) Pub. No.: US 2026/0253843 A1
(43) Pub. Date: Aug. 27, 2026

(54) PLASMA PROCESSING APPARATUS AND SHOWER HEAD

(71) Applicant: Tokyo Electron Limited, Minato-ku (JP)

(72) Inventors: Kazushi KANEKO, Nirasaki-shi (JP); Satoru KAWAKAMI, Nirasaki-shi (JP)

(21) Appl. No.: 19/642,713

(22) Filed: Apr. 9, 2026

Related U.S. Application Data
(63) Continuation of application No. PCT/JP2024/034551, filed on Sep. 27, 2024.

(30) Foreign Application Priority Data
Oct. 11, 2023 (JP) 2023-176057

(51) Int. Cl. H01J 37/32; C23C 16/455; C23C 16/505

(52) U.S. Cl. CPC H01J 37/3244; C23C 16/45565; C23C 16/505; H01J 37/32165; H01J 2237/024; H01J 2237/332

(57) ABSTRACT

The substrate processing apparatus includes a processing container, a second holder, a gas supply, an electromagnetic wave generator, and a showerhead. The processing container includes a processing chamber for providing a processing space and a reaction chamber for providing a plasma generation space. The electromagnetic wave generator generates an electromagnetic wave for plasma excitation. The electromagnetic wave supply supplies the electromagnetic wave into the reaction chamber. The showerhead partitions the processing chamber and the reaction chamber and includes a resonator array structure and through-holes configured to bring the processing chamber into communication with the reaction chamber, the resonator array structure including a plurality of resonators capable of resonating with a magnetic field component of the electromagnetic wave, the plurality of resonators having a size smaller than the wavelength of the electromagnetic wave and arranged in a direction of the same plane.

### CROSS-REFERENCE TO RELATED APPLICATION

This application is a bypass continuation application of international application No. PCT/JP2024/034551 having an international filing date of Sep. 27, 2024 and designating the United States, the international application being based upon and claiming the benefit of priority from Japanese Patent Application No. 2023-176057, filed on Oct. 11, 2023, the entire contents of which are incorporated herein by reference.

### TECHNICAL FIELD

The present disclosure relates to a plasma processing apparatus and a showerhead.

### BACKGROUND

The method disclosed in Patent Document 1 includes providing a substrate into a reaction chamber, depositing a silicon carbide film having a first thickness on the substrate, exposing the silicon carbide film having the first thickness to a remote hydrogen plasma process to densify the silicon carbide film having the first thickness, depositing a silicon carbide film having a second thickness on the silicon carbide film having the first thickness, and exposing the silicon carbide film having the second thickness to a remote hydrogen plasma process to densify the silicon carbide film having the second thickness. Patent Document 2 discloses a showerhead including a head and a magnetic field generation part. The head has a first surface and a second surface opposite the first surface. A chamber is formed in the head, and a plurality of holes, each of which is opened through the first surface and the second surface facing the chamber to communicate with the chamber, are provided in the head. The magnetic field generation part is configured to generate a magnetic field between the first surface and the second surface within the plurality of holes.

### PRIOR ART DOCUMENTS

### Patent Documents

Patent Document 1: Japanese International Publication No. 2020-502797
Patent Document 2: Japanese Laid-Open Publication No. 2019-054164

### SUMMARY

According to the present disclosure, there is provided a plasma processing apparatus, including: a processing container configured to include a processing chamber for providing a space in which a substrate is processed and a reaction chamber for providing a space in which plasma is generated; a substrate holder configured to hold the substrate within the processing chamber; a gas supply configured to supply a processing gas into the reaction chamber; an electromagnetic wave generator configured to generate an electromagnetic wave for plasma excitation to be supplied into the reaction chamber; an electromagnetic wave supply configured to supply the electromagnetic wave into the reaction chamber; and a showerhead configured to partition the processing chamber and the reaction chamber and to include a resonator array structure and through-holes configured to bring the processing chamber into communication with the reaction chamber, the resonator array structure including a plurality of resonators capable of resonating with a magnetic field component of the electromagnetic wave, the plurality of resonators having a size smaller than the wavelength of the electromagnetic wave and arranged in a direction of the same plane, and wherein the showerhead supplies radicals contained in the plasma generated in the reaction chamber to the processing chamber through the through-holes.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of the configuration of a plasma processing apparatus according to a first embodiment.

FIG. 2 is a plan view showing an example of the configuration of a support member and a resonator array structure according to the first embodiment as viewed from above.

FIG. 3 is a view showing an example of the configuration of a card-shaped resonator according to the first embodiment.

FIG. 4 is a view showing an example of the configuration of the card-shaped resonator according to the first embodiment.

FIG. 5 is a view showing another example of the configuration of the card-shaped resonator according to the first embodiment.

FIG. 6 is a view showing an example of a cross section of the card-shaped resonator according to the first embodiment.

FIG. 7 is a view showing an example of the relationship between the S21 value of the card-shaped resonator and the microwave frequency.

FIG. 8 is a view showing an example of the resonant frequency of the resonator according to the first embodiment.

FIG. 9 is a perspective view showing an example of the resonator array structure according to the first embodiment.

FIG. 10 is a view showing an example of a plasma generation region and a high-density radical region in a portion of the A-A cross section in FIG. 9.

FIG. 11 is a diagram showing an example of a portion of a cross section of a resonator array structure according to Modification 1.

FIG. 12 is a schematic cross-sectional view showing an example of the configuration of a plasma processing apparatus according to a second embodiment.

FIG. 13 is a plan view showing an example of the configuration of a support member and a resonator array structure according to the second embodiment as viewed from above.

FIG. 14 is a cross-sectional view showing an example of the B-B cross section in FIG. 13.

FIG. 15 is a diagram showing an example of the plan-view shape and the C-C cross section of a single resonator according to the second embodiment.

FIG. 16 is a cross-sectional view showing an example of the D-D cross section in FIG. 15.

FIG. 17 is a cross-sectional view showing an example of the E-E cross section in FIG. 15.

FIG. 18 is a diagram showing another example of the plan-view shape and the C-C cross section of a single resonator according to the second embodiment.

FIG. 19 is a diagram showing an example of a plasma generation region and a high-density radical region in a portion of the B-B cross section in FIG. 13.

FIG. 20 is a diagram showing an example of the relationship between the position of a ring member and the plasma generation region.

FIG. 21 is a diagram showing an example of the relationship between the position of the ring member and the plasma generation region.

FIG. 22 is a diagram showing an example of the relationship between the position of a shield and the plasma generation region.

FIG. 23 is a diagram showing an example of a portion of a cross section of a resonator array structure according to Modification 2.

FIG. 24 is a schematic cross-sectional view showing an example of the configuration of an apparatus main body according to Modification 3.

FIG. 25 is a schematic cross-sectional view showing an example of the configuration of an apparatus main body according to Modification 4.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a plasma processing apparatus and a showerhead disclosed herein will be described below in detail with reference to the accompanying drawings. However, the disclosed techniques are not limited to the following embodiments.

In a plasma processing apparatus using microwaves for plasma excitation, the microwave power supplied into the processing container may be increased to increase the electron density of plasma. The higher the microwave power supplied into the processing container, the higher the electron density of the plasma can be.

It is known that when the electron density of plasma reaches a certain upper limit by increasing the microwave power supplied into the processing container, the dielectric constant of the space inside the processing container becomes negative. This upper limit of the electron density is appropriately referred to as a “cutoff density.” In addition, the refractive index is known as an index indicating whether microwaves propagate through a space. The refractive index N is expressed by the following formula (1):

N=\sqrt{ε}\sqrt{μ} (1)

where ε is a dielectric constant, and μ is a magnetic permeability.

Since the magnetic permeability is generally positive, when the dielectric constant of the space inside the processing container becomes negative, the refractive index of the space inside the processing container becomes a pure imaginary number according to the above formula (1). As a result, the microwaves are attenuated and cannot propagate through the space inside the processing container. When the electron density of plasma reaches the cutoff density, the microwaves cannot propagate through the space inside the processing container, and the microwave power is not sufficiently absorbed by the plasma. As a result, there is a problem in that the plasma generated inside the processing container is prevented from densifying over a wide area. While the microwaves have been described above by way of example, the same problem also arises in a plasma processing apparatus that uses electromagnetic waves in a band from a very-high frequency (VHF) to an ultra-high frequency (UHF).

In addition, a plasma processing apparatus sometimes uses a shower plate to control the distribution of a processing gas introduced into a chamber and generate plasma to improve in-plane uniformity. However, the energy used to generate the plasma from the processing gas with a controlled distribution may change a gas distribution, thereby reducing process uniformity. Furthermore, in a plasma processing apparatus, plasma generated in a plasma generation chamber is sometimes introduced into the chamber using a shower plate to control a plasma distribution. However, in so-called remote plasma, the distance between a plasma source and a substrate to be processed is long, which may lead to plasma diffusion and a decrease in plasma density (radical density). In addition, when the processing gas or the plasma passes through the through-holes of the shower plate, reflection, loss, and recombination due to collisions of ions and radicals may occur, thereby reducing the plasma density (radical density). Such low-density radicals result in a slower substrate processing rate. Therefore, generation of high-density radicals is expected.

### First Embodiment

### [Configuration of Plasma Processing Apparatus]

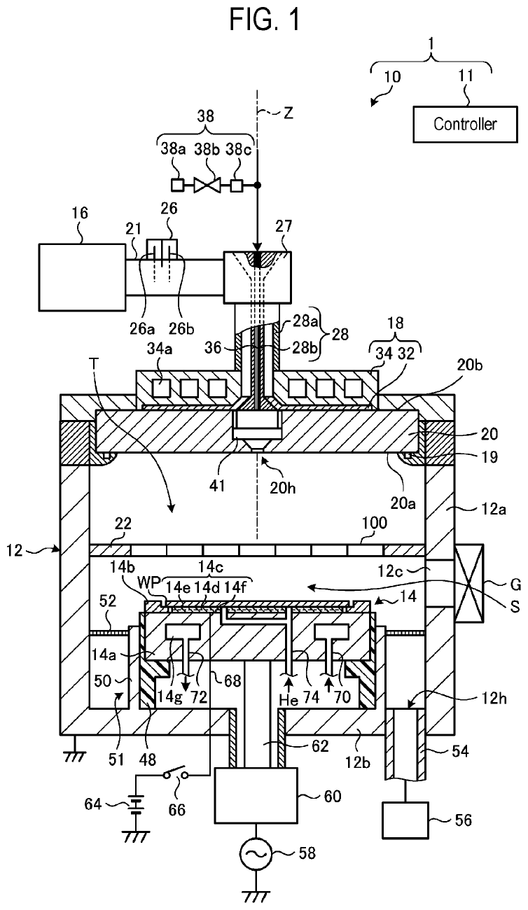

FIG. 1 is a schematic cross-sectional view showing an example of the configuration of a plasma processing apparatus 1 according to a first embodiment. The plasma processing apparatus 1 includes an apparatus main body 10 and a controller 11. The apparatus main body 10 includes a processing container 12, a stage 14, a microwave output device (an example of an electromagnetic wave generator) 16, an antenna 18, a dielectric window 20, and a resonator array structure 100.

The processing container 12 is formed in a substantially cylindrical shape using, for example, aluminum whose surface is anodized, and provides a substantially cylindrical processing space S and a substantially cylindrical generation space T therein. The processing space S is an example of a processing chamber, and the generation space T is an example of a reaction chamber. The processing container 12 is grounded for safety. The processing container 12 also has a sidewall 12a and a bottom portion 12b. The central axis of the sidewall 12a is defined as an axis Z. The bottom portion 12b is provided on the lower end side of the sidewall 12a. An exhaust port 12h for gas exhaust is provided in the bottom portion 12b. The upper end of the sidewall 12a is open. The inner wall surface of the sidewall 12a faces the processing space S and the generation space T. That is, the sidewall 12a is provided so that the inner wall surface thereof faces the processing space S and the generation space T.

The sidewall 12a has an opening 12c for loading and unloading a workpiece WP. The opening 12c is opened and closed by a gate valve G.

The dielectric window 20 is provided at the upper end of the sidewall 12a to close the opening formed at the upper end of the sidewall 12a from above. The lower surface 20a of the dielectric window 20 faces the generation space T. In other words, the dielectric window 20 is provided so that the lower surface 20a thereof faces the generation space T. An O-ring 19 is arranged between the dielectric window 20 and the upper end of the sidewall 12a.

The stage 14 is accommodated in the processing container 12. The stage 14 is disposed so as to face the resonator array structure 100, which also serves as a showerhead, in the direction of the axis Z. The space between the stage 14 and the resonator array structure 100 is the processing space S. The workpiece WP is placed on the stage 14.

The stage 14 includes a base 14a and an electrostatic chuck 14c. The base 14a is made of a conductive material such as aluminum or the like and has a generally disk-like shape. The base 14a is arranged in the processing chamber 12 such that the central axis of the base 14a substantially coincides with the axis Z.

The base 14a is supported by a cylindrical support part 48 made of an insulating material and extending in the Z-axis direction. A conductive cylindrical support part 50 is provided on the outer periphery of the cylindrical support part 48. The cylindrical support part 50 extends from the bottom portion 12b of the processing container 12 toward the dielectric window 20 along the outer periphery of the cylindrical support part 48. An annular exhaust path 51 is formed between the cylindrical support part 50 and the sidewall 12a. The stage 14 may be configured to be movable in the vertical direction (Z-axis direction) by a drive mechanism (not shown), thereby changing the distance between the lower surface of the resonator array structure 100 and the upper surface of the electrostatic chuck 14c. This makes it possible to adjust the energy level depending on the residence time.

An annular baffle plate 52 having a plurality of through-holes formed in the thickness direction is provided above the exhaust path 51. The above-mentioned exhaust port 12h is provided below the baffle plate 52. An exhaust device 56 including a vacuum pump such as a turbomolecular pump or the like and an automatic pressure control valve is connected to the exhaust port 12h via an exhaust pipe 54. The exhaust device 56 can reduce the pressure in the processing space S and the generation space T to a desired vacuum level.

The base 14a functions as a high-frequency electrode. A high-frequency power supply 58 for RF bias is electrically connected to the base 14a via a power feed rod 62 and a matching unit 60. The high-frequency power supply 58 supplies bias power of a predetermined frequency (e.g., 13.56 MHz) suitable for controlling the energy of ions attracted to the workpiece WP, to the base 14a via the matching unit 60 and the power feed rod 62.

The matching unit 60 accommodates a matcher for matching the impedance on the high-frequency power supply 58 side with the impedance on the side of loads mainly consisting of the electrodes, the plasma, and the processing chamber 12. The matcher includes a blocking capacitor for generating a self-bias. If an RF bias is not used, the high-frequency power supply 58, the matching unit 60 and the power feed rod 62 may be omitted.

The electrostatic chuck 14c is provided on the upper surface of the base 14a. The electrostatic chuck 14c attracts and holds the workpiece WP by an electrostatic force. The electrostatic chuck 14c has a generally disc-like outer shape and includes an electrode 14d, an insulating film (dielectric film) 14e, and an insulating film (dielectric film) 14f. The electrostatic chuck 14c is arranged on the upper surface of the base 14a so that the central axis of the electrostatic chuck 14c substantially coincides with the axis Z. The electrode 14d of the electrostatic chuck 14c is formed of a conductive film and is provided between the insulating films 14e and 14f. A DC power supply 64 is electrically connected to the electrode 14d via a coated wire 68 and a switch 66. The electrostatic chuck 14c attracts and holds the workpiece WP on its upper surface by the electrostatic force generated by a DC voltage applied from the DC power supply 64. The upper surface of the electrostatic chuck 14c is a mounting surface on which the workpiece WP is mounted, and faces the processing space S. That is, the electrostatic chuck 14c is provided so that the upper surface thereof, which is the mounting surface, faces the processing space S. Furthermore, an edge ring 14b is provided on the base 14a. The edge ring 14b is disposed so as to surround the workpiece WP and the electrostatic chuck 14c. The edge ring 14b is also called a focus ring.

A flow path 14g is provided inside the base 14a. A coolant is supplied to the flow path 14g from a chiller unit (not shown) via a pipe 70. The coolant supplied to the flow path 14g is returned to the chiller unit via a pipe 72. The coolant, whose temperature is controlled by the chiller unit, circulates through the flow path 14g of the base 14a, thereby controlling the temperature of the base 14a. By controlling the temperature of the base 14a, the temperature of the workpiece WP on the electrostatic chuck 14c on the base 14a is controlled via the electrostatic chuck 14c on the base 14a.

The stage 14 is also provided with a pipe 74 for supplying a heat transfer gas such as a He gas between the upper surface of the electrostatic chuck 14c and the back surface of the workpiece WP.

The microwave output device 16 outputs microwaves (an example of electromagnetic waves) for exciting the processing gas supplied into the processing chamber 12. The microwave output device 16 is capable of adjusting the frequency, power, bandwidth, and other parameters of the microwaves. For example, the microwave output device 16 can generate a single-frequency microwave by setting the microwave bandwidth to approximately zero. The microwave output device 16 can also generate microwaves containing multiple frequency components within a predetermined frequency bandwidth (hereinafter referred to as “broadband microwaves”). The power of these multiple frequency components may be the same, or only the central frequency component within the band may have a higher power than other frequency components. The microwave output device 16 can adjust the microwave power, for example, within a range of 0 W to 5000 W. The microwave output device 16 can adjust the microwave frequency or the central frequency of the broadband microwaves, for example, within a range of 2.3 GHz to 2.5 GHZ, and can adjust the bandwidth of the broadband microwaves, for example, within a range of 0 MHz to 100 MHz. In addition, the microwave output device 16 can adjust the frequency pitch (carrier pitch) of the multiple frequency components of the broadband microwaves within a range of, for example, 0 to 25 kHz.

The apparatus main body 10 also includes a waveguide 21, a tuner 26, a mode converter 27, and a coaxial waveguide 28. The output portion of the microwave output device 16 is connected to one end of the waveguide 21. The other end of the waveguide 21 is connected to the mode converter 27. The waveguide 21 is, for example, a rectangular waveguide. The tuner 26 is provided on the waveguide 21. The tuner 26 includes movable plates 26a and 26b. By adjusting the amount of protrusion of each of the movable plates 26a and 26b with respect to the internal space of the waveguide 21, it is possible to match the impedance of the microwave output device 16 with the impedance of the load.

The mode converter 27 converts the mode of the microwaves output from the waveguide 21 and supplies the mode-converted microwaves to the coaxial waveguide 28. The coaxial waveguide 28 includes an outer conductor 28a and an inner conductor 28b. The outer conductor 28a and the inner conductor 28b have a substantially cylindrical shape. The outer conductor 28a and the inner conductor 28b are arranged above the antenna 18 so that the central axes of the outer conductor 28a and the inner conductor 28b substantially coincide with the axis Z. The coaxial waveguide 28 transmits the microwaves whose mode has been converted by the mode converter 27 to the antenna 18.

The antenna 18 supplies the microwaves to the generation space T. The antenna 18 is an example of an electromagnetic wave supply. The antenna 18 is provided on the upper surface 20b of the dielectric window 20, and supplies the microwaves to the generation space T through the dielectric window 20. The antenna 18 includes a dielectric plate 32 and a cooling jacket 34.

The dielectric plate 32 is formed in a substantially disk-like shape from a dielectric material such as quartz or the like. The dielectric plate 32 is provided on the upper surface 20b of the dielectric window 20 so that the central axis of the dielectric plate 32 substantially coincides with the axis Z. The cooling jacket 34 is provided on the dielectric plate 32. In other words, the dielectric plate 32 is provided between the cooling jacket 34 and the dielectric window 20.

The surface of the cooling jacket 34 is conductive. A flow path 34a is formed inside the cooling jacket 34. A coolant is supplied to the flow path 34a from the chiller unit (not shown). The lower end of the outer conductor 28a is electrically connected to the upper surface of the cooling jacket 34. The lower end of the inner conductor 28b passes through openings formed at the center of the cooling jacket 34 and the dielectric plate 32 and extends to near the upper surface 20b of the dielectric window 20. In other words, the antenna 18 forms a monopole antenna.

The microwaves propagated through the coaxial waveguide 28 in a TEM mode propagate from the inner conductor 28b through the dielectric plate 32 and are radiated in a TM01 mode into the generation space T via the dielectric window 20. In other words, by not providing a slot plate in the antenna 18, the microwaves are radiated into the generation space T without resonation. That is, the antenna 18 can suppress the generation of plasma directly below the lower surface 20a of the dielectric window 20. In addition, the magnetic field components of the microwaves radiated into the generation space T are distributed in the circumferential direction around the Z axis.

The resonator array structure 100 is formed by arranging a plurality of resonators that can resonate with the magnetic field component of microwaves and that are smaller in size than the wavelength of the microwaves, and is located, for example, above the opening 12c in the processing container 12 while being supported by the support member 22. Furthermore, the resonator array structure 100 partitions the processing space S and the generation space T and has through-holes 125 (described later) that bring the processing space S into communication with the generation space T. In other words, the resonator array structure 100 is an example of the showerhead having the through-holes 125.

Since the microwaves are radiated from the antenna 18 to the generation space T in a non-resonant manner, high-density plasma is not generated. By positioning the resonator array structure 100 inside the processing container 12, the microwaves supplied to the generation space T by the antenna 18 can be resonated with the plurality of resonators of the resonator array structure 100. Resonance of the microwaves with the plurality of resonators allows the microwaves to be efficiently supplied to the resonator array structure 100 inside the processing container 12, and allows the magnetic permeability of the resonator array structure 100 to be negative. When the magnetic permeability of the resonator array structure 100 is negative, even if the electron density of plasma generated in the resonator array structure 100 reaches the cutoff density and the dielectric constant of the resonator array structure 100 is negative, the refractive index becomes a real number according to the above formula (1). Therefore, the microwaves can propagate inside the generation space T even if the plasma generation region is formed above the resonator array structure 100. Thus, even if the electron density of the plasma generated in the plasma generation region above the resonator array structure 100 in the generation space T reaches the cutoff density, the microwaves can propagate beyond the skin depth of the plasma, and the microwave power is efficiently absorbed by the plasma. As a result, high-density plasma can be generated over a wide area beyond the skin depth of the plasma. That is, according to the plasma processing apparatus 1 of this embodiment, the resonator array structure 100 is located inside the processing container 12, which makes it possible to achieve high-density plasma over a wide area.

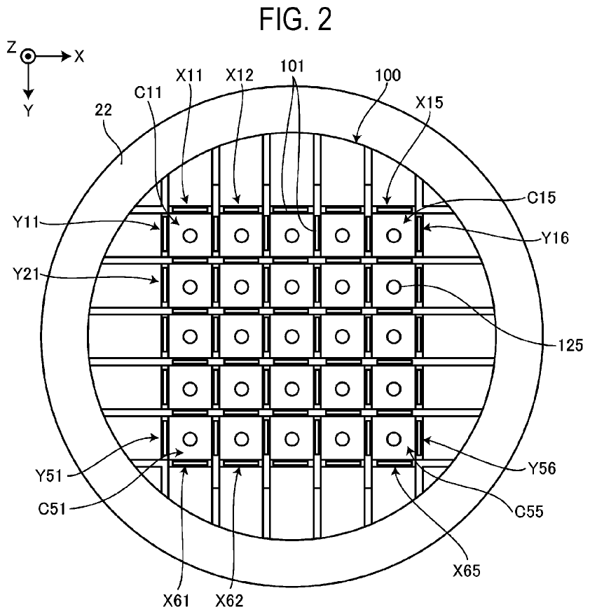

Now, the detailed configuration of the resonator array structure 100 will be described with reference to FIGS. 1 and 2. FIG. 2 is a plan view showing an example of the configuration of the support member 22 and the resonator array structure 100 according to the first embodiment as viewed from above. In FIG. 2, the support member 22 and the resonator array structure 100 are shown in a disk shape.

As shown in FIGS. 1 and 2, the resonator array structure 100 is disposed above the opening 12c in the processing container 12 and is supported by the support member 22. The support member 22 may be a sealing structure that seals the space between the processing space S and the generation space T.

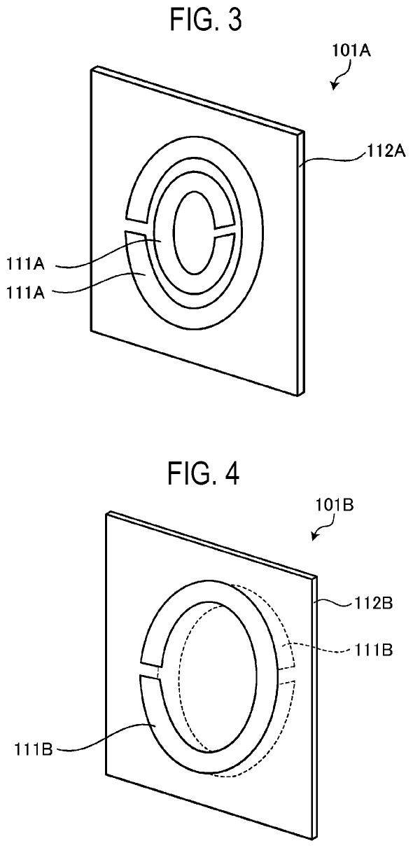

The resonator array structure 100 is formed by arranging a plurality of resonators 101 in a lattice pattern. The resonators 101 are capable of resonating with the magnetic field component of microwaves and have a size smaller than the wavelength of the microwaves. Specifically, the plurality of resonators 101 include at least one of the resonators 101A and 101B shown in FIGS. 3 and 4. Each of the plurality of resonators 101 forms a series resonant circuit consisting of a capacitor-equivalent element and a coil-equivalent element. The series resonant circuit is realized by patterning a conductor on a plane.

FIG. 3 is a diagram showing an example of the configuration of a card-shaped resonator 101A according to the first embodiment. The card-shaped resonator 101A shown in FIG. 3 has a structure in which two C-shaped concentric conductor ring members 111A arranged in an opposite direction are stacked on one surface of a dielectric plate 112A. Capacitor-equivalent elements are formed on the opposing surfaces of the inner and outer ring members 111A and on both ends of each ring member 111A, and coil-equivalent elements are formed along each ring member 111A. Thus, the resonator 101A can constitute a series resonant circuit.

FIG. 4 is a diagram showing an example of the configuration of a card-shaped resonator 101B according to the first embodiment. The card-shaped resonator 101B shown in FIG. 4 has a structure in which a dielectric plate 112B is disposed between two C-shaped ring members 111B made of a conductor and arranged adjacent to each other in opposite directions. That is, in the resonator 101B, the dielectric plate 112B is sandwiched between the two C-shaped ring members 111B arranged in opposite directions. Capacitor-equivalent elements are formed on the opposing surfaces of the two C-shaped ring members 111B and on both ends of each ring member 111B, and coil-equivalent elements are formed along each ring member 111B. Thus, the resonator 101B can form a series resonant circuit. The card-shaped resonator 101B can also be expressed as being formed in a card shape for each pair of two C-shaped ring members 111B.

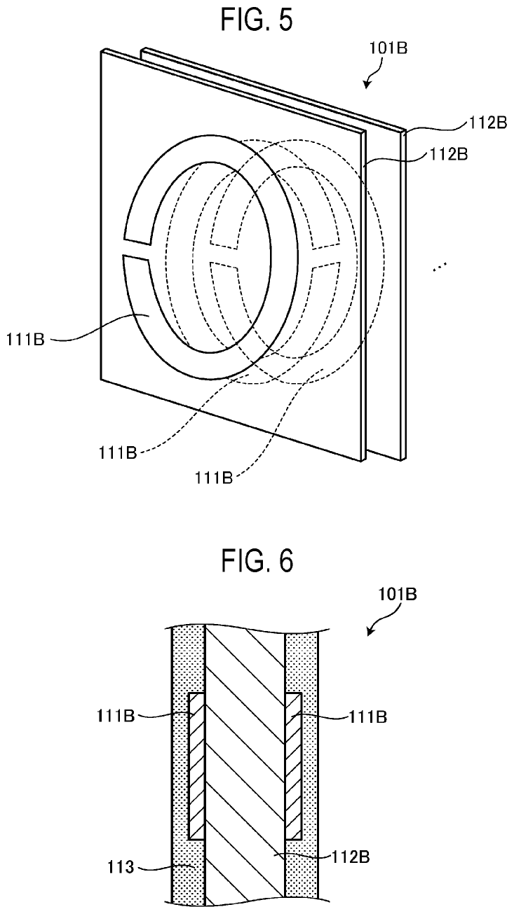

In the resonator 101B shown in FIG. 4, the number of arrangements (hereinafter also referred to as the “number of layers”) of the ring members 111B is two. However, the number of layers of the ring members 111B may be greater than two. FIG. 5 is a diagram showing another example of the configuration of the card-shaped resonator 101B according to the first embodiment. The resonator 101B shown in FIG. 5 has a structure in which a dielectric plate 112B is arranged between N (N≥2) C-shaped ring members 111B made of a conductor and arranged adjacent to each other in opposite directions. Even with this structure, the resonator 101B can form a series resonant circuit.

Furthermore, an insulating film may be formed on each of the plurality of resonators 101. FIG. 6 is a diagram showing an example of the cross section of the card-shaped resonator 101B according to the first embodiment. FIG. 6 shows a side cross section of the resonator 101B shown in FIG. 4. An insulating film (an example of a dielectric film) 113 is formed on the surface of the resonator 101B. The material of the film 113 is, for example, ceramic. The thickness of the film 113 is, for example, in the range of 0.001 mm to 2 mm. By forming the insulating film 113 on each of the plurality of resonators 101, it is possible to suppress abnormal discharge in each of the plurality of resonators 101.

Referring again to FIG. 1, a conduit 36 is provided inside the inner conductor 28b of the coaxial waveguide 28. The conduit 36 extends through the inside of the inner conductor 28b and is connected to a gas supply 38.

The gas supply 38 supplies a processing gas for processing the workpiece WP to the conduit 36. The gas supply 38 includes a gas supply source 38a, a valve 38b, and a flow rate controller 38c. The gas supply source 38a is a processing gas supply source. The valve 38b controls the supply and stop of supply of the processing gas from the gas supply source 38a. The flow rate controller 38c is, for example, a mass flow controller, and controls the flow rate of the processing gas supplied from the gas supply source 38a.

Furthermore, the apparatus main body 10 also includes an injector 41. The injector 41 supplies a gas from the conduit 36 to the through-hole 20h formed in the dielectric window 20. The gas supplied to the through-hole 20h in the dielectric window 20 is sprayed into the generation space T and excited in the plasma generation region above the resonator array structure 100 by the microwaves supplied from the antenna 18 to the generation space T via the dielectric window 20. Thus, the processing gas is converted into plasma in the plasma generation region above the resonator array structure 100 inside the generation space T, and the radicals contained in the plasma and the inactivated processing gas are supplied to the processing space S through the through-holes 125 described below. Furthermore, the ions contained in the plasma are recombined to form radicals as they pass through the through-holes 125, and the radicals are similarly supplied to the processing space S. The processing space S becomes a high-density radical region where the workpiece WP is processed by the radicals.

The controller 11 has a processor, a memory, and an input/output interface. The memory is a computer readable non-transient storage medium that stores programs, process recipes, and the like. The processor reads a program from the memory and executes the program thus read, thereby controlling each part of the apparatus main body 10 via the input/output interface based on the process recipes stored in the memory.

For example, when plasma is generated in the plasma generation region above the resonator array structure 100 inside the generation space T, the controller 11 controls the microwaves supplied to the generation space T by the antenna 18 so that they resonate with the plurality of resonators 101 in a target frequency band higher than the resonant frequency of the plurality of resonators 101. Here, the resonant frequency is, for example, a frequency at which the transmission characteristic value (e.g., S21 value) of the plurality of resonators 101 becomes a minimum value.

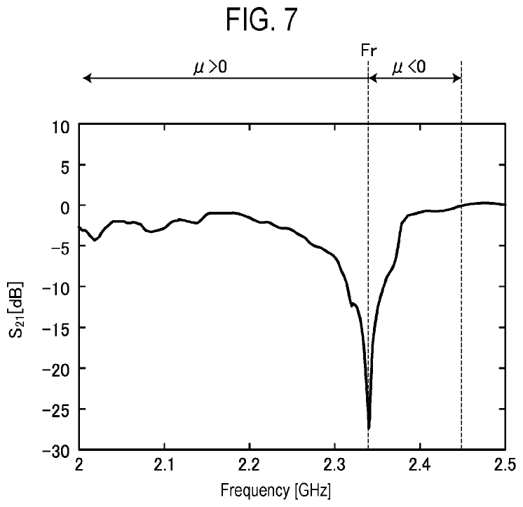

FIG. 7 shows an example of the relationship between the S21 value of the card-shaped resonator and the frequency of microwaves. When the frequency of the microwaves supplied to the processing space S and the generation space T by the antenna 18 matches the resonant frequency Fr (approximately 2.35 GHZ) of each resonator 101, the S21 value of each resonator 101 becomes minimal, and the microwaves and each resonator 101 are resonated. The resonance of the microwaves and each resonator 101 is maintained even in a predetermined frequency band (e.g., approximately 0.1 GHZ) higher than the resonant frequency Fr of each resonator 101. In the predetermined frequency band higher than the resonant frequency Fr of each resonator 101, the resonance of the microwaves and each resonator 101 can allow both the permittivity and the permeability to become negative in the plasma generation region above the resonator array structure 100 inside the generation space T. Accordingly, as can be seen from the above formula (1), microwave propagation is possible in the plasma generation region above the resonator array structure 100 inside the generation space T. In this embodiment, the target frequency band is set to a predetermined frequency band (e.g., about 0.1 GHZ) higher than the resonance frequency Fr of each resonator 101. The target frequency band is preferably, for example, within 0.05 times the resonance frequency Fr of each resonator 101. The resonance frequency Fr of the card-shaped resonator 101 can be measured, for example, by a vector network analyzer in which a transmitting/receiving antenna is arranged in a direction parallel to the ring member 111B of the card-shaped resonator 101B.

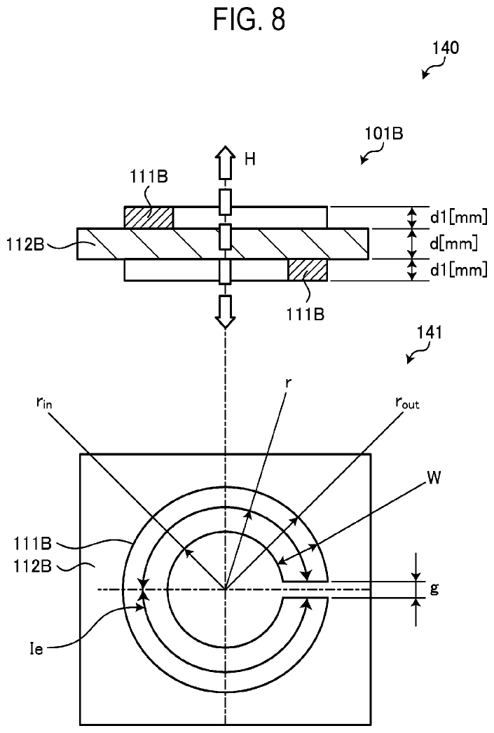

Next, the resonant frequency of the resonator 101B will be described using FIG. 8. FIG. 8 is an explanatory diagram showing an example of the resonant frequency of the resonator according to the first embodiment. As shown in the cross section 140 of FIG. 8, the resonator 101B may be considered to have a structure in which a dielectric plate 112B is sandwiched between two C-shaped ring members 111B. When a magnetic field H that penetrates the C-shaped ring member 111B of the resonator 101B is generated, an induced current Ie is generated in the C-shaped ring member 111B. The coating 113 surrounding the outside of the C-shaped ring member 111B is omitted from FIG. 8.

On the other hand, the resonant frequency of the resonator 101B can be calculated from the dimensions of the cross section 140 and the plane 141 in FIG. 8. That is, the resonant frequency of the resonator 101B can be calculated from the dimensions of the C-shaped ring member 111B and the thickness of the dielectric plate 112B sandwiched between the two C-shaped ring members 111B, as shown in the following formulas (2) to (5). Formula (2) is used to calculate the inductance L_{MA} of the resonator 101B. Formula (3) is used to calculate the capacitance C_{half} of the capacitance C_{MA} of the resonator 101B, which corresponds to the upper or lower half of the plane 141. Formula (4) is used to calculate the capacitance C_{MA} of the resonator 101B. Formula (5) is used to calculate the resonant frequency Fr of the resonator 101B.

$${L}_{M A} = {μ}_{0} r ( log ( 4 π ) - 1 ) \qquad ( 2 )$$

$${C}_{half} = ε {ε}_{0} \frac{s}{d} = ε {ε}_{0} \frac{( π ( {r}_{o u t}^{2} - {r}_{i n}^{2} ) - {s}_{split} ) / 2}{{d}_{PTFE}} \qquad ( 3 )$$

$${C}_{M A} = \frac{1}{\frac{1}{{c}_{half}} + \frac{1}{{c}_{half}}} \qquad ( 4 )$$

$$Fr = \frac{1}{2 π \sqrt{{L}_{M A} {C}_{M A}}} \qquad ( 5 )$$

In formula (2), r represents the radius from the center of the C-shaped ring member 111B to the center of the width of the C, and μ₀ represents the magnetic permeability of a vacuum. In formula (3), C_{half} represents the capacitance of the resonator 101B corresponding to the upper or lower half of the plane 141. Furthermore, in formula (3), ε represents the dielectric constant, co represents the dielectric constant (electric constant) of a vacuum, S represents the area of the upper or lower half of the C-shaped ring member 111B, and d represents the spacing between the two C-shaped ring members 111B. Furthermore, in formula (3), rₒᵤₜ represents the outer radius of the C-shaped ring member 111B, rᵢₙ represents the inner radius of the C-shaped ring member 111B, and Sₛₚₗᵢₜ represents the area of the gap between the C-shaped ring members 111B. Sₛₚₗᵢₜ can be approximately calculated as the area of a rectangle from the width W of the C-shaped ring members 111B shown in the plane 141 and the gap g between the C-shaped ring members. Furthermore, in formula (3), d_{PTFE} represents the distance between the two C-shaped ring members 111B when polytetrafluoroethylene (PTFE) is used as the dielectric plate 112B. As shown in the cross section 140, it is preferable that the two C-shaped ring members 111B have the same thickness d1.

In formula (5), the resonant frequency Fr of the resonator 101B is calculated based on the inductance L_{MA} and the capacitance C_{MA} calculated using formulas (2) and (4). The resonant frequency Fr decreases as the outer radius rₒᵤₜ and the inner radius rᵢₙ of the C-shaped ring member 111B becomes large, and decreases as the thickness d of the dielectric plate 112B sandwiched between the two C-shaped ring members 111B becomes small. The resonant frequency Fr also decreases as the number of layers of the C-shaped ring members 111B increases. In other words, by adjusting the outer radius rₒᵤₜ and inner radius rᵢₙ of the ring member 111B and the thickness d of the dielectric plate 112B, it is possible to form resonators 101 having different resonant frequencies Fr. In this embodiment, the C-shaped ring members 111A and 111B are described as having a circular ring shape with a notch in one portion. However, the present disclosure is not limited thereto. The shape of the ring member is not limited to the circular ring shape, but may be, for example, an oval ring shape, a triangular ring shape, a square ring shape, a polygonal ring shape, or any other ring shape having a notch (corresponding to the gap g).

Regarding the propagation of electromagnetic waves through a plurality of resonators, the relationship between the resonant frequency and the refractive index, permittivity and permeability has been reported, for example, by D. R. Smith, D. C. Vier, T. Koschny, and C. M. Soukoulis et al. in “Electromagnetic parameter retrieval from inhomogeneous metamaterials” in “PHYSICAL REVIEW E 71, 036617 (2005).”

In this way, by allowing the microwaves to resonate with the plurality of resonators 101 in the target frequency band higher than the resonant frequency Fr of the plurality of resonators 101, microwave propagation beyond the skin depth of the plasma becomes possible even when the electron density of plasma reaches the cutoff density. Therefore, the microwave power can be efficiently absorbed by the plasma. As a result, high-density plasma can be generated over a wide area beyond the skin depth of the plasma. That is, according to the plasma processing apparatus 1 of this embodiment, by allowing the microwaves to resonate with the plurality of resonators 101 in the target frequency band higher than the resonant frequency Fr of the plurality of resonators 101, high-density plasma can be achieved over a wide area.

### [Details of the Resonator Array Structure]

Next, the details of the resonator array structure 100 will be described. As shown in FIG. 2, the resonator array structure 100 includes the card-shaped resonators 101 arranged in a lattice pattern. In the following description, the resonator array structure 100 may be referred to as a metamaterial 100, and the card-shaped resonators 101 may be referred to as meta-atoms 101. In the example shown in FIG. 2, the meta-atoms 101 are arranged so that the cells C surrounded by the meta-atoms 101 form five columns in the X-axis direction and five rows in the Y-axis direction (cells C11 to C55). In other words, the meta-atoms 101 are arranged in six rows and five columns, with their longitudinal directions extending along the X-axis direction, just like X11, X12, . . . , X15, . . . , X61, X62, . . . , X65. The meta-atoms 101 are arranged in five rows and six columns, with their longitudinal directions extending along the Y-axis, just like Y11, Y21, . . . , Y51, . . . , Y16, Y26, . . . , Y56. The lattice width and depth of cell C are equal to or larger than the outer shape of the C-shaped ring member of the meta-atom 101 (e.g., the ring member 111B).

Furthermore, a through-hole 125 is formed at the center of the bottom surface of each cell C of the resonator array structure 100. When controlling the density of plasma, the meta-atoms 101 constituting the peripheral cells C and the meta-atoms 101 near the central cell C may have different resonant frequencies Fr.

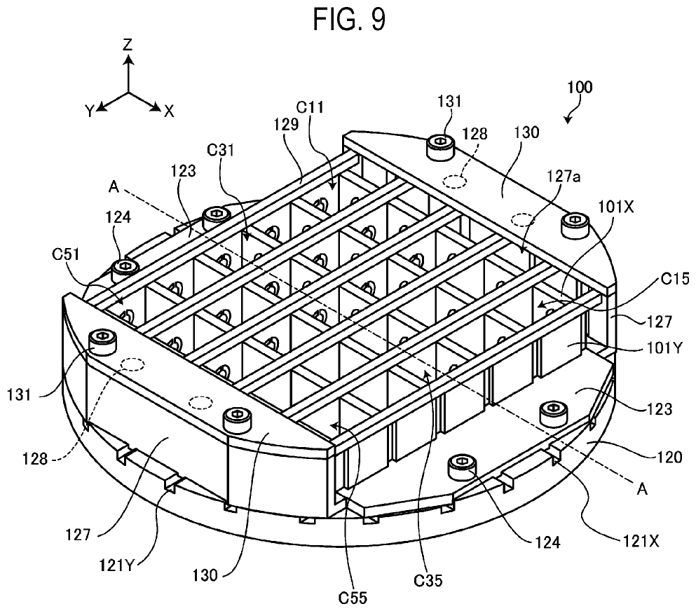

FIG. 9 is a perspective view showing an example of the resonator array structure according to the first embodiment. In FIG. 9, ring members are drawn on some of the meta-atoms 101 to make the orientation of the meta-atoms 101 easier to understand. However, in reality, the surfaces are covered with a dielectric material (insulating film).

The resonator array structure 100 shown in FIG. 9 includes a base plate 120. The base plate 120 is made of a dielectric material such as quartz or ceramics. The base plate 120 is provided with a plurality of grooves 121X extending in the X-axis direction and a plurality of grooves 121Y extending in the Y-axis direction, into which the meta-atoms 101 are fitted. Furthermore, as shown in FIG. 2, a through-hole 125 is provided in the portion of the base plate 120 that becomes the bottom surface of each cell.

The meta atom 101 is fitted into each of the grooves 121X and 121Y. In the following description, the meta atom 101 fitted into the groove 121X may be referred to as a meta atom 101X, and the meta atom 101 fitted into the groove 121Y may be referred to as a meta atom 101Y. Furthermore, the meta atom 101X is assumed to be wider than the meta atom 101Y, and the ends of the meta atom 101X are assumed to be in contact with each other. Each of the regions surrounded by the meta atom 101X and the meta atom 101Y is a cell C. In the example of FIG. 9, five rows and five columns of cells, i.e., cells C11 to C55, are formed.

Side pressing members 123 are fixed to the base plate 120 using screws 124 so as to contact one side of the meta-atoms 101Y at locations Y11 to Y51 and Y16 to Y56 shown in FIG. 2 among the outermost meta-atoms 101. The side pressing members 123 and the screws 124 are an example of pressing members, and are made of ceramics such as alumina, which is a dielectric material.

The side pressing members 127 are fixed to the base plate 120 using screws 128 so as to contact one side of the meta-atoms 101X at locations X11 to X15 and X61 to X65 shown in FIG. 2 among the outermost meta-atoms 101. A space 127a is formed between the side pressing members 127 and the outermost meta-atoms 101X. The space 127a is provided in consideration of plasma generation. The side pressing members 127 and the screws 128 are an example of pressing members and are made of ceramics such as alumina, which is a dielectric material.

A pressing member 129 presses down the meta-atoms 101X and 101Y between the two side pressing members 127. The pressing member 129 is installed between the two side pressing members 127 so as to press down continuously on the upper portion of the meta-atom 101Y in the longitudinal direction and also press down the upper end of the meta-atom 101X. In other words, the pressing member 129 is installed parallel to the side pressing members 123. The pressing member 129 is made of ceramics such as alumina, which is a dielectric material.

A member 130 is disposed above the side pressing member 127 in order to fix the pressing member 129. An end of the pressing member 129 is sandwiched between the side pressing member 127 and the member 130. The member 130 is fixed to the side pressing member 127 by a screw 131. The member 130 and the screw 131 are an example of a pressing member and are made of ceramics such as alumina, which is a dielectric material.

The through-holes 125 bring the generation space T faced by each cell C into communication with the processing space S faced by the surface of the base plate 120 opposite the surface on which each cell C is formed, i.e., the lower surface of the base plate 120. The through-holes 125 have, for example, a circular cross section. The through-holes 125 have a diameter of, for example, 10 mm or less, which allows ions to be recombined and allows radicals and an inactivated processing gas to pass from the generation space T to the processing space S. It is more preferable that the through-holes 125 have a diameter of, for example, 2 mm or less. In other words, the through-holes 125 have a diameter that does not allow ions to pass from the generation space T to the processing space S.

### High-Density Radical Generation in the First Embodiment

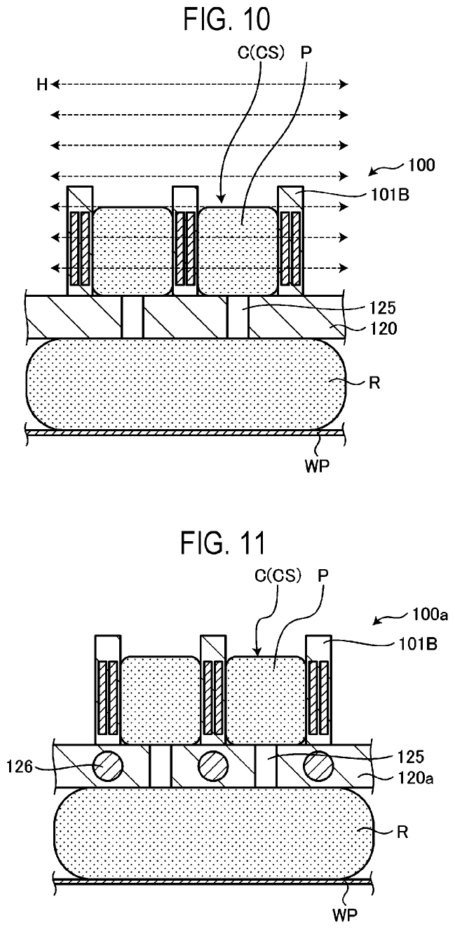

Next, the plasma generation region and high-density radical region will be described using FIG. 10. FIG. 10 is a diagram showing an example of the plasma generation region and high-density radical region in a portion of the A-A cross section in FIG. 9. As shown in FIG. 10, in the resonator array structure 100, since the magnetic field H is directed to penetrate the resonator 101B of each cell C, the resonator 101B resonates and excitation of plasma P occurs in each cell C. In other words, the cell space CS of each cell C serves as the plasma generation region. The processing container 12 is depressurized by the exhaust device 56, thereby generating a flow toward the exhaust port 12h. Therefore, the processing gas supplied to the generation space T through the through-holes 20h excites plasma P in each cell C and flows into the processing space S through the through-holes 125. In other words, a high-density radical region R, where radicals are highly concentrated, is formed on the underside of the base plate 120. The workpiece WP is processed by the high-density radicals in the high-density radical region R.

As described above, in this embodiment, it is possible to generate high-density radicals. That is, since a large number of radicals are supplied to the surface of the workpiece WP without diffusing the high-density plasma (high-density radicals), the processing rate of the workpiece WP can be improved. Furthermore, since the resonator array structure 100, which serves as the plasma source, also serves as a shower plate (showerhead), the distance between the workpiece WP and the resonator array structure 100 can be set short, thereby suppressing plasma loss due to diffusion. Moreover, since the flow rate distribution can be controlled through each through-hole 125, the in-plane uniformity of the workpiece WP can be improved. In addition, since the resonator array structure 100, which serves as the shower plate, is discharged by itself, dry cleaning can be easily performed. Furthermore, in the resonator array structure 100, the resonance state of each resonator 101 can be controlled by controlling the frequency of the supplied microwaves. That is, the dry cleaning position can be changed by using different plasma modes (a negative refractive index (ε<0 and μ<0), a positive refractive index (&>0 and μ>0), and an imaginary refractive index (ε<0 and μ>0)).

### (Modification 1)

Next, Modification 1 of the first embodiment will be described using FIG. 11. FIG. 11 is a diagram showing an example of a portion of a cross section of a resonator array structure according to Modification 1. The resonator array structure 100a of Modification 1 shown in FIG. 11 is realized by adding a temperature control function to the resonator array structure 100 of the first embodiment. The resonator array structure 100a includes a heater 126 embedded in a base plate 120a for temperature control. In the resonator array structure 100a, temperature control can be achieved by heating the base plate 120a with the heater 126. Alternatively, instead of the heater 126, a heat medium flow path may be provided, and the temperature of the base plate 120a may be controlled by circulating a temperature-controlled heat medium from a chiller unit (not shown) through the flow path in the base plate 120a. The heat medium may also be a coolant such as cooling water or the like. In this case, temperature control can be achieved by cooling the base plate 120a.

### Second Embodiment

In the first embodiment described above, the resonator array structure 100 is used in which the plurality of resonators 101 are arranged perpendicularly on the flat base plate 120. However, a flat resonator array structure in which the resonators 101 are arranged in the direction of the same plane may also be used. An embodiment using such a resonator array structure will be described as a second embodiment. In the second embodiment, the same components as those of the plasma processing apparatus 1 according to the first embodiment are designated by the same reference numerals, and descriptions of the overlapping components and operations will be omitted.

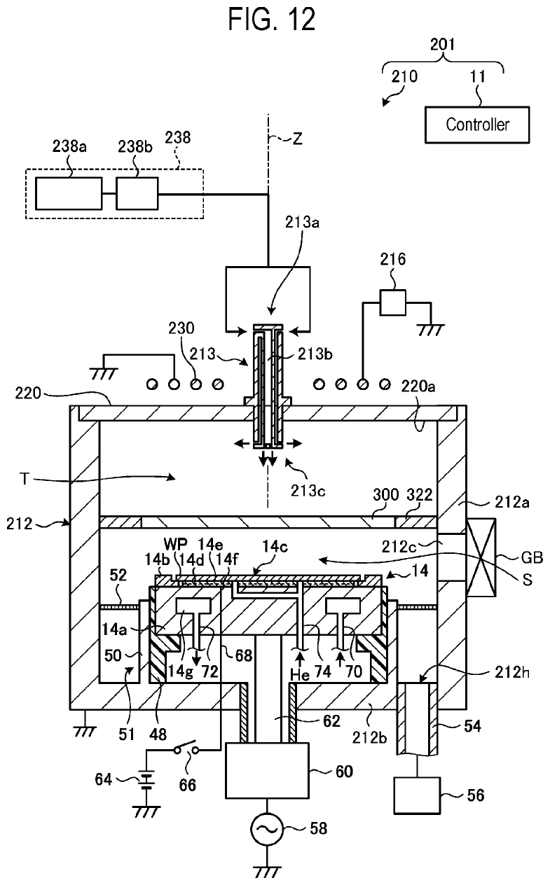

FIG. 12 is a schematic cross-sectional view showing an example of the configuration of the plasma processing apparatus according to the second embodiment. The plasma processing apparatus 201 shown in FIG. 12 includes an apparatus main body 210 instead of the apparatus main body 10 of the plasma processing apparatus 1 according to the first embodiment. The plasma processing apparatus 201 shown in FIG. 12 is configured, for example, as an inductively coupled plasma processing apparatus. The apparatus main body 210 includes a processing container 212, a stage 14, an RF (Radio Frequency) power supply (an example of an electromagnetic wave generator) 216, a dielectric window 220, an antenna 230, a gas supply 238, and a resonator array structure 300. The apparatus main body 210 further includes a central gas injector 213. The central gas injector 213 is disposed above the stage 14 and attached to the central opening of the dielectric window 220. The antenna 230 is disposed in the upper portion of the processing container 212 (dielectric window 220) or above (outside) the processing container 212 (dielectric window 220).

The processing container 212 is formed in a substantially cylindrical shape from, for example, aluminum whose surface is anodized, and provides a substantially cylindrical processing space S and a substantially cylindrical generation space T therein. The processing vessel 212 is grounded for safety. The processing container 212 further has a sidewall 212a and a bottom portion 212b. The central axis of the sidewall 212a is defined as an axis Z. The bottom portion 212b is provided on the lower end side of the sidewall 212a. An exhaust port 212h for gas exhaust is provided in the bottom portion 212b. The upper end of the sidewall 212a is open. The inner wall surface of the sidewall 212a faces the processing space S and the generation space T. That is, the sidewall 212a is provided so that the inner wall surface thereof faces the processing space S and the generation space T.

The sidewall 212a has an opening 212c for loading and unloading a workpiece WP, which is opened and closed by a gate valve GB.

A dielectric window 220 is provided at the upper end of the sidewall 212a, and closes the opening at the upper end of the sidewall 212a from above. A lower surface 220a of the dielectric window 220 faces the generation space T. In other words, the dielectric window 220 is provided so that the lower surface 220a thereof faces the generation space T.

The RF (Radio Frequency) power supply 216 is coupled to the antenna 230 and configured to generate a source RF signal (source RF power) for plasma generation via at least one impedance matching circuit. In one embodiment, the source RF signal has a frequency within a range of 10 MHz to 3000 MHz. In one embodiment, the RF power supply 216 may be configured to generate multiple source RF signals having different frequencies. The one or more source RF signals thus generated are supplied to the antenna 230. As described above, the RF power supply 216 is an example of an electromagnetic wave generator and an example of a radio-frequency power supply. The antenna 230 is an example of an electromagnetic wave supply.

The antenna 230 includes one or more coils. In one embodiment, the antenna 230 may include an outer coil and an inner coil arranged coaxially. In this case, the RF power supply 216 may be connected to both the outer coil and the inner coil, or to either the outer coil or the inner coil. In the former case, the same RF generator within the RF power supply 216 may be connected to both the outer coil and the inner coil, or separate RF generators may be connected to the outer coil and the inner coil separately. In one embodiment, the antenna 230 is a planar coil formed in a substantially circular spiral shape (planar spiral shape). In other words, the antenna 230 is wound in a loop shape. The magnetic field generated by the antenna 230 is oriented in the direction of the axis Z. The opening of the antenna 230 may have any shape, such as a circular shape, an elliptical shape, or a polygonal shape (e.g., a square shape, a triangular shape, or the like).

Furthermore, when the antenna 230 includes an outer coil and an inner coil, the outer coil functions as a primary coil connected to the RF power supply 216. In one embodiment, the outer coil is a planar coil formed in a substantially circular spiral shape. The inner coil functions as a secondary coil inductively coupled to the primary coil. That is, the inner coil is not connected to the RF power supply 216. In one embodiment, the inner coil is a planar coil formed in a substantially circular ring shape. In one embodiment, the inner coil is connected to a variable capacitor, and the direction and magnitude of the current flowing through the inner coil are controlled by controlling the capacitance of the variable capacitor. The outer coil and the inner coil may be positioned at the same height or at different heights. In one embodiment, the inner coil is positioned lower than the outer coil. The antenna 230 does not have a strong resonator, thereby suppressing plasma generation directly below the dielectric window 220 and supplying electromagnetic waves perpendicularly to the resonator array structure 300.

The gas introduction part is configured to introduce at least one processing gas from the gas supply 238 into the generation space T. In one embodiment, the gas introduction part includes a center gas injector (CGI) 213. The center gas injector 213 is disposed above the stage 14 and the resonator array structure 300, and is attached to a central opening formed in the dielectric window 220. The center gas injector 213 has at least one gas supply port 213a, at least one gas flow path 213b, and at least one gas inlet 213c. The processing gas supplied to the gas supply port 213a passes through the gas flow path 213b and is introduced into the generation space T from the gas inlet 213c, where the processing gas is excited by the electromagnetic waves supplied from the antenna 230 to the generation space T via the dielectric window 220. This converts the processing gas into plasma in the generation space T. The radicals and the inactivated processing gas contained in the plasma are supplied to the processing space S through the through-holes 308, which will be described later. Furthermore, the ions contained in the plasma are recombined to form radicals as they pass through the through-holes 308. These radicals are similarly supplied to the processing space S. The processing space S becomes a high-density radical region, and the workpiece WP is processed by these radicals. The gas introduction part may include, in addition to or instead of the center gas injector 213, one or more side gas injectors (SGIs) attached to one or more openings formed in the sidewall 212a.

The gas supply 238 may include at least one gas source 238a and at least one flow controller 238b. In one embodiment, the gas supply 238 is configured to supply at least one processing gas from the corresponding gas source 238a to the gas introduction part through the corresponding flow controller 238b. Each flow controller 238b may include, for example, a mass flow controller or a pressure-controlled flow controller. In addition, the gas supply 238 may include one or more flow modulation devices that modulate or pulse the flow rate of at least one processing gas.

The resonator array structure 300 is formed by arranging a plurality of resonators that can resonate with the magnetic field component of an electromagnetic wave and that are smaller in size than the wavelength of the electromagnetic wave, and is located, for example, above the opening 212c in the processing container 212 while being supported by a support member 322. The resonator array structure 300 partitions the processing space S and the generation space T and has a through-hole 308 (described later) that brings the processing space S into communication with the generation space T. In other words, the resonator array structure 300 is an example of a showerhead that has through-holes 308. The support member 322 may also be a sealing structure that seals the processing space S and the generation space T.

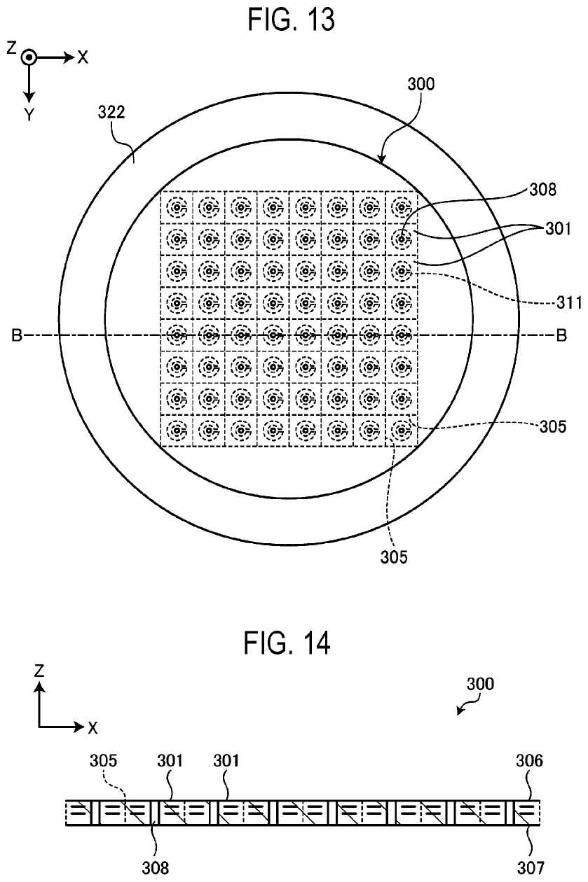

The detailed configuration of the resonator array structure 300 will now be described with reference to FIGS. 12 and 13. FIG. 13 is a plan view showing an example of the configuration of the support member and the resonator array structure according to the second embodiment as viewed from above. In FIG. 13, the support member 322 and the resonator array structure 300 are shown in a disk shape.

As shown in FIGS. 12 and 13, the resonator array structure 300 is disposed above the opening 212c in the processing container 212 and supported by the support member 322.

The resonator array structure 300 is formed by arranging a plurality of resonators 301, each of which can resonate with the magnetic field component of an electromagnetic wave and has a size smaller than the wavelength of the electromagnetic wave, in a lattice pattern. Specifically, as shown in FIG. 13, the plurality of resonators 301 are arranged in a plane parallel to the lower surface 220a of the dielectric window 220 in the flat resonator array structure 300. That is, when viewed from the side of the lower surface 220a, the C-shaped ring members 311, which are shown transparently, are arranged in a lattice pattern so that the C shape is visible.

The resonator array structure 300 includes, for example, eight rows and eight columns of resonators 301 arranged therein. Although the boundaries between the resonators 301 are indicated as boundaries 305, in reality, the resonators 301 are integrally formed as the resonator array structure 300. The resonators 301 may be formed separately and then fitted into a lattice frame or bonded to each other to form the resonator array structure 300. Each of the plurality of resonators 301 forms a series resonant circuit consisting of a capacitor-equivalent element and a coil-equivalent element. The series resonant circuit is realized by patterning a conductor on a plane. The magnetic field generated by the antenna 230 is directed to pass through the C-shaped ring member 311.

FIG. 14 is a cross-sectional view showing an example of the B-B cross section in FIG. 13. As shown in FIG. 14, in the B-B cross section of the resonator array structure 300, the cross sections of the plurality of resonators 301 appear side by side. As in FIG. 13, the boundaries between the plurality of resonators 301 are indicated as boundaries 305. Here, the first surface 306 of the resonator array structure 300 faces the dielectric window 220 (the generation space T side), and the second surface 307 thereof faces the stage 14 (the processing space S side). In addition, a through-hole 308 is provided at the center of each of the plurality of resonators 301.

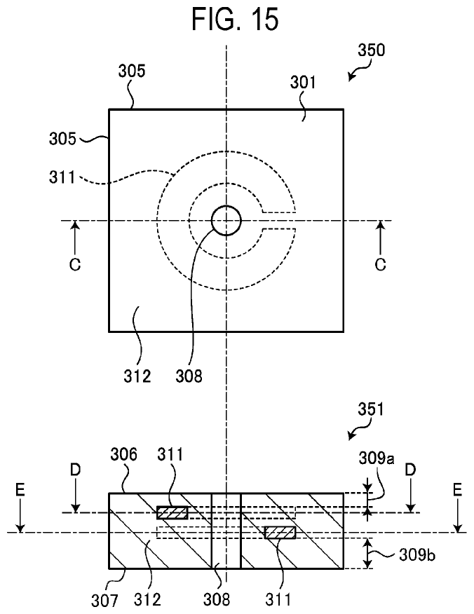

FIG. 15 shows an example of the plane and the C-C cross section of a single resonator according to the second embodiment. FIG. 15 shows the plane 350 of the single resonator 301 and the C-C cross section 351 of the plane 350 by using one resonator 301 as an example among the plurality of resonators 301 formed integrally. As indicated as the plane 350 and the cross section 351, the single resonator 301 is located within a region surrounded by a boundary 305. That is, in this embodiment, the resonator 301 has two C-shaped ring members 311, each surrounded by a dielectric body 312. The dielectric body 312 is formed so that the thickness 309a from the first C-shaped ring member 311 to the first surface 306 is smaller than the thickness 309b from the second C-shaped ring member 311 to the second surface 307. This allows the resonator array structure 300 to selectively generate plasma on the first surface 306 side, which is the generation space T side. That is, the resonator array structure 300 can control the plasma generation surface by adjusting the thickness of the dielectric body 312 from each ring member 311 of the resonator 301 to the surface.

The through-hole 308 brings the generation space T faced by the first surface 306 into communication with the processing space S faced by the second surface 307. The through-hole 308 has, for example, a circular cross section. The through-hole 308 has, for example, a diameter of 10 mm or less, which allows ions to be recombined and allows radicals and inactivated processing gas to pass from the generation space T to the processing space S. More preferably, the through-hole 308 has a diameter of, for example, 2 mm or less. That is, the through-hole 308 has a diameter that does not allow ions to pass from the generation space T to the processing space S. That is, radicals and inactivated processing gas contained in the plasma generated in the generation space T on the first surface 306 side are supplied to the processing space S on the second surface 307 side through the through-hole 308. In addition, ions contained in the plasma are recombined to form radicals as they pass through the through-hole 308. These radicals are similarly supplied to the processing space S. The processing space S becomes a high-density radical region, and the workpiece WP is processed by the radicals.

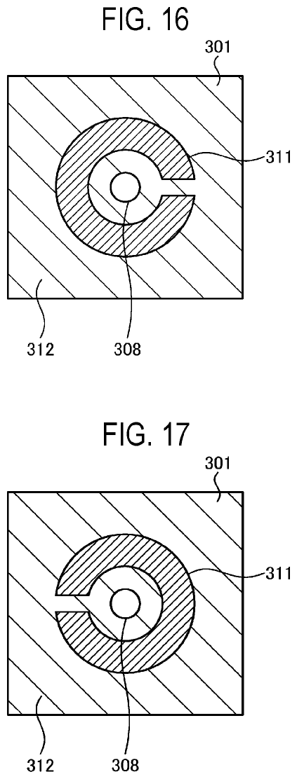

FIG. 16 is a cross-sectional view showing an example of the D-D cross section in FIG. 15. FIG. 17 is a cross-sectional view showing an example of the E-E cross section in FIG. 15. As shown in the cross-section 351 in FIG. 15 and FIGS. 16 and 17, a single resonator 301 has a structure in which a dielectric body 312 is arranged between two C-shaped ring members 311 made of a conductor and arranged adjacent to each other in opposite directions. That is, in the resonator 301, the dielectric body 312 is sandwiched between the two C-shaped ring members 311 arranged in opposite directions. Furthermore, as described above, a through-hole 308 is provided at the center of the two C-shaped ring members 311. Capacitor-equivalent elements are formed on the opposing surfaces of the two C-shaped ring members 311 and at both ends of each ring member 311, and coil-equivalent elements are formed along each ring member 311. Thus, the resonator 301 can form a series resonant circuit. In the resonator 301 shown in FIGS. 15 to 17, the number of arrangements (hereinafter also referred to as the “number of layers”) of the C-shaped ring members 311 is two. However, the number of layers of the C-shaped ring members 311 may be greater than two. In this case, the resonator 301 has a structure in which the C-shaped ring members 311 are arranged adjacent to each other in opposite directions and in which a dielectric body 312 is arranged between the C-shaped ring members 311. The resonant frequency of the resonator 301 is the same as that of the resonator 101 of the first embodiment, and therefore the description thereof will be omitted.

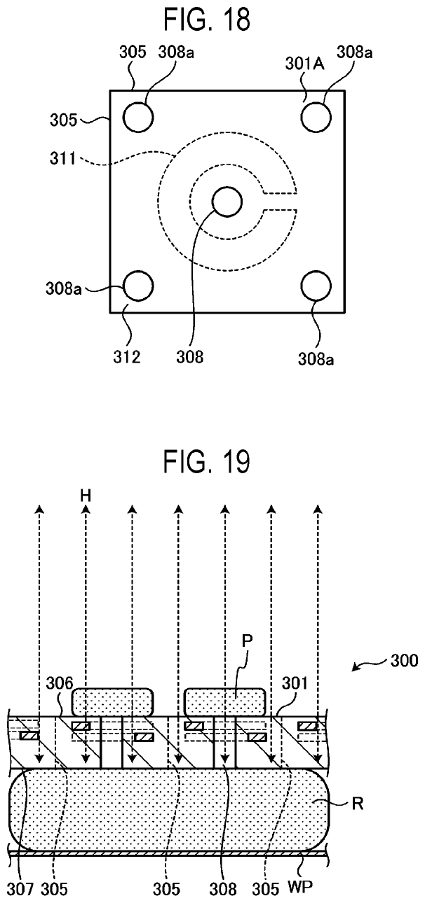

FIG. 18 is a diagram showing another example of the plane and the C-C cross section of the single resonator according to the second embodiment. The single resonator 301 shown in FIG. 15 may further include a plurality of through-holes 308a in portions of the area surrounded by the boundary 305 so as to avoid the C-shaped ring member 311, as in the single resonator 301A shown in FIG. 18. Just like the through-hole 308, each of the plurality of through holes 308a brings the generation space T faced by the first surface 306 into communication with the processing space S faced by the second surface 307. In the example of FIG. 18, the single resonator 301A has one through-hole 308 and four through-holes 308a. In this way, the flow rate distribution may be controlled by the number of through-holes 308 and 308a that bring the generation space T into communication with the processing space S.

### High-Density Radical Generation in the Second Embodiment

Next, the plasma generation region and the high-density radical region will be described using FIGS. 19 to 21. FIG. 19 shows an example of the plasma generation region and the high-density radical region in a portion of the B-B cross section in FIG. 13. As shown in FIG. 19, in the resonator array structure 300, since the magnetic field H is directed to penetrate each resonator 301, each resonator 301 resonates and plasma P is excited on the first surface 306 side of each resonator 301. In other words, the first surface 306 side of the resonator array structure 300 serves as the plasma generation region. Since the inside of the processing container 212 is depressurized by the exhaust device 56, a flow toward the exhaust port 212h is generated. Accordingly, the processing gas supplied to the generation space T from the gas inlet 213c excites the plasma P on the first surface 306 side of each resonator 301, and flows into the processing space S through the through-hole 308. That is, a high-density radical region R where the radicals are highly concentrated is formed on the second surface 307 side of the resonator array structure 300. The workpiece WP is processed by the high-density radicals in the high-density radical region R.

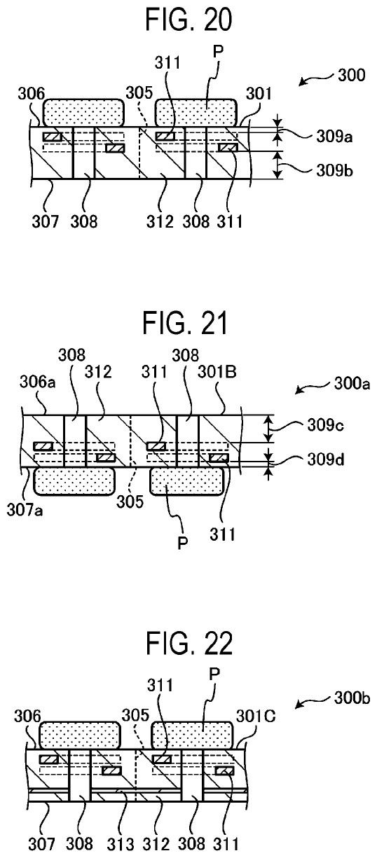

FIGS. 20 and 21 are diagrams showing an example of the relationship between the position of the ring member and the plasma generation region. As shown in FIG. 20, in the resonator array structure 300, the thickness 309a of the dielectric body 312 from the first C-shaped ring member 311 to the first surface 306 is smaller than the thickness 309b of the dielectric body 312 from the second C-shaped ring member 311 to the second surface 307. The smaller the thickness of the dielectric body 312 from the C-shaped ring member 311 to the surface, the more easily it absorbs the electromagnetic wave power. Thus, the plasma is more easily excited on the thinner surface of the dielectric body 312 of each resonator 301. For example, in the resonator array structure 300, by making the thickness 309b at least twice the thickness 309a, plasma is more easily excited on the first surface 306 side which is the thickness 309a side of each resonator 301.

On the other hand, in the resonator array structure 300a shown in FIG. 21, the thickness 309c of the dielectric body 312 from the first C-shaped ring member 311 to the first surface 306a is larger than the thickness 309d of the second C-shaped ring member 311 to the second surface 307a. In this case, by making the thickness 309c at least twice the thickness 309d, plasma is more likely to be excited on the second surface 307a side of each resonator 301B which is the thickness 309d side. If the thicknesses 309c and 309d are substantially the same, plasma is excited on both the first surface 306a side and the second surface 307a side. As shown in FIGS. 20 and 21, the plasma generation surface can be controlled by the position of the C-shaped ring member 311 within the resonator 301. In this embodiment, radicals are supplied to the processing space S. Therefore, the resonator array structure 300 shown in FIG. 20 is preferred.

FIG. 22 is a diagram showing an example of the relationship between the position of a shield and the plasma generation region. The resonator array structure 300b shown in FIG. 22 further includes a shield 313 between the second C-shaped ring member 311 of the resonator array structure 300 and the second surface 307. The shield 313 is a conductive member made of a material such as aluminum, and is formed of a Faraday shield. The shield 313 shields the electric field of the electromagnetic waves radiated from the antenna 230 from reaching the lower portion of the resonator array structure 300b (the second surface 307 side). Since there is no electric field below the resonator array structure 300b, no voltage is applied thereto. Therefore, it is possible to suppress plasma excitation and discharge below the resonator array structure 300b (the second surface 307 side).

In this manner, high-density radicals can also be generated in this embodiment. That is, a large number of radicals are supplied to the surface of the workpiece WP without diffusing the high-density plasma (high-density radicals), thereby improving the processing rate of the workpiece WP. Furthermore, since the resonator array structure 300, which is the plasma source, also functions as a shower plate (showerhead), it is possible to suppress the loss of plasma due to diffusion. In addition, since the flow rate distribution can be controlled at each through-hole 308, it is possible to improve the in-plane uniformity of the workpiece WP.

### (Modification 2)

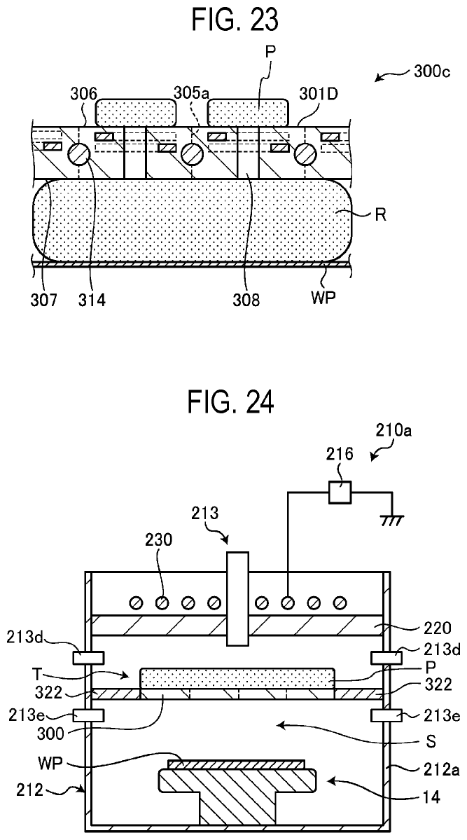

Next, Modification 2 of the second embodiment will be described using FIG. 23. FIG. 23 is a diagram showing an example of a portion of a cross section of a resonator array structure according to Modification 2. The resonator array structure 300c of Modification 2 shown in FIG. 23 is realized by adding a temperature control function to the resonator array structure 300 according to the second embodiment. The resonator array structure 300c includes heaters 314 embedded within the boundaries 305a of the respective resonators 301D to provide a temperature control function. The heaters 314 are positioned to avoid the through-holes 308. The resonator array structure 300c can be temperature-controlled by heating the resonator array structure 300c itself with the heaters 314. Alternatively, instead of the heaters 314, a heat medium flow path may be provided, and a temperature-controlled heat medium may be circulated through the flow path of the resonator array structure 300c from a chiller unit (not shown), so that the temperature of the resonator array structure 300c can be controlled. The heat medium may be a coolant such as cooling water, in which case the temperature of the resonator array structure 300c can be controlled by cooling the same.

### (Modifications 3 and 4)

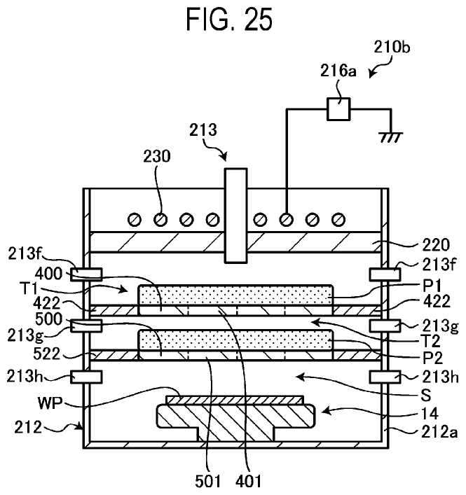

Next, Modifications 3 and 4 of the second embodiment will be described using FIGS. 24 and 25. Modifications 3 and 4 are examples of application to so-called pre-activation plasma, which uses multiple processing gases. The description of Modifications 3 and 4 will focus primarily on the arrangement of the resonator array structure, the RF power supply, and the gas introduction part, and therefore, descriptions will be given using diagrams obtained by simplifying FIG. 12.

FIG. 24 is a schematic cross-sectional view showing an example of the configuration of an apparatus main body according to Modification 3. As shown in FIG. 24, the apparatus main body 210a according to Modification 3 is different from the apparatus main body 210 according to the second embodiment in that, in addition to the center gas injector 213, a plurality of side gas injectors 213d and 213e are provided as gas introduction parts on the sidewall 212a.

The plurality of side gas injectors 213d are provided on the sidewall 212a closer to the dielectric window 220 than the resonator array structure 300 and the support member 322, and are controlled by the controller 11 to introduce a first processing gas into the generation space T. The center gas injector 213 is also controlled by the controller 11 to introduce the first processing gas into the generation space T. From the center gas injector 213 and the side gas injectors 213d, one or more first processing gases selected from a nitrogen (N₂) gas, a hydrogen (H₂) gas, an argon gas, a neon gas, and the like are introduced into the generation space T.

The plurality of side gas injectors 213e are provided on the sidewall 212a closer to the stage 14 than the resonator array structure 300 and the support member 322, and are controlled by the controller 11 to introduce a second processing gas into the processing space S. From the side gas injectors 213e, for example, one or more second processing gases such as a nitrogen (N₂) gas and an ammonia (NH₃) gas are introduced into the processing space S.

When the RF power supply 216 is controlled by the controller 11 to supply electromagnetic waves and when the electromagnetic waves are supplied from the antenna 230, plasma P of the first processing gas is generated on the first surface 306 side of the resonator array structure 300 in the generation space T. Radicals (active species) contained in the generated plasma P are supplied to the processing space S through the through-holes 308. In the processing space S, the radicals supplied from the generation space T side are mixed with the second processing gas, and new radicals (active species), such as NH* and NH2* molecules (where the symbol*indicates a radical), are generated. The workpiece WP is processed by the radicals generated in the processing space S.

Instead of the support member 322, the resonator array structure 300 may be arranged on a grid plate provided at approximately the same position as the support member 322. In this case, the second processing gas may be supplied to the processing space S via the grid plate. The grid plate may be made of, for example, a metal or a dielectric material.

As described above, in Modification 3, radicals can be generated and controlled arbitrarily in the processing space S and the generation space T. Furthermore, since electromagnetic waves are wirelessly supplied from the antenna 230 to the resonator array structure 300, it is possible to suppress deactivation of the plasma P generated in the generation space T. Moreover, in the resonator array structure 300, the distribution of the plasma P can be controlled by the arrangement of the resonators 301. In addition, the processing rate of films (encapsulation films) such as a silicon nitride film and a silicon carbide film can be improved by irradiating high-density radicals of hydrogen, nitrogen, argon, neon, or the like.

FIG. 25 is a schematic cross-sectional view showing an example of the configuration of an apparatus main body according to Modification 4. As shown in FIG. 25, the apparatus main body 210b according to Modification 4 differs from the apparatus main body 210 according to the second embodiment in that the resonator array structures 400 and 500 are arranged in two stages to provide generation spaces T1 and T2 and a processing space S. An RF power supply 216a capable of supplying electromagnetic waves to each of the two stages of the resonator array structures 400 and 500 is also provided. In addition to the center gas injector 213, a plurality of side gas injectors 213f to 213 h are provided as gas introduction parts on the sidewall 212a.

The resonator array structure 400 has the same configuration as the resonator array structure 300 and is supported by a support member 422. The space between the resonator array structure 400 and the dielectric window 220 is a generation space T1. The resonator array structure 500 has the same configuration as the resonator array structure 300 and is supported by a support member 522. The space between the resonator array structure 400 and the resonator array structure 500 is a generation space T2, and the space between the resonator array structure 500 and the stage 14 is a processing space S. The resonators 401 and 501 of the resonator array structure 400 and the resonator array structure 500 differ in resonance frequency.

The RF power supply 216a generates, for example, a source RF signal having an output frequency Fo(1) that resonates with each resonator 401 of the resonator array structure 400, and a source RF signal having an output frequency Fo(2) that resonates with each resonator 501 of the resonator array structure 500. The source RF signals having the output frequencies Fo(1) and Fo(2) are supplied to the antenna 230. The RF power supply 216a may output the electromagnetic waves having output frequencies Fo(1) and Fo(2) in a single-peak waveform by FM modulation or the like, or in a broadband waveform that becomes multi-tone.

A plurality of side gas injectors 213f are provided on the sidewall 212a closer to the dielectric window 220 than the resonator array structure 400 and the support member 422, and are controlled by the controller 11 to introduce a first processing gas into the generation space T1. The center gas injector 213 is also controlled by the controller 11 to introduce a first processing gas into the generation space T1. From the center gas injector 213 and the side gas injectors 213f, one or more first processing gases selected from a nitrogen (N₂) gas, a hydrogen (H₂) gas, an argon gas, a neon gas, and the like are introduced into the generation space T1.

A plurality of side gas injectors 213g are provided on the sidewall 212a between the resonator array structure 400 and the support member 422 and the resonator array structure 500 and the support member 522, and are controlled by the controller 11 to introduce a second processing gas into the generation space T2. From the side gas injectors 213g, for example, one or more second processing gases such as a nitrogen (N₂) gas and an ammonia (NH₃) gas are introduced into the generation space T2.

A plurality of side gas injectors 213h are provided on the sidewall 212a closer to the stage 14 than the resonator array structure 500 and the support member 522, and are controlled by the controller 11 to introduce a third processing gas into the processing space S. The side gas injectors 213h introduce, for example, one or more third processing gases selected from a nitrogen (N₂) gas and an ammonia (NH₃) gas into the processing space S. The second processing gas and the third processing gas used in Modification 4 may be the same as or different from the second processing gas used in Modification 3.

When the RF power supply 216a is controlled by the controller 11 to supply electromagnetic waves and when the electromagnetic waves are supplied from the antenna 230, in the generation space T1, the electromagnetic waves having the output frequency Fo(1) generate plasma P1 of the first processing gas on the upper surface side of the resonator array structure 400. Radicals (active species) contained in the generated plasma P1 are supplied to the generation space T2 through the through-holes of the resonator array structure 400.

In the generation space T2, the radicals supplied from the generation space T1 are mixed with the second processing gas, thereby generating new radicals (active species), such as NH* and NH₂* molecules. Furthermore, in the generation space T2, plasma P2 of a mixed gas is generated on the upper surface side of the resonator array structure 500 by the electromagnetic waves having the output frequency Fo(2). Since the generation space T1 has a negative refractive index, the electromagnetic waves having the output frequency Fo(2) passe through the generation space T1 and the resonator array structure 400 and resonates with each resonator of the resonator array structure 500. The radicals (active species) contained in the generated plasma P2 are supplied to the processing space S through the through-holes of the resonator array structure 500.

In the processing space S, the radicals supplied from the generation space T2 side are mixed with the third processing gas, and new radicals (active species), such as NH* and NH₂* molecules, are generated. The radicals generated in the processing space S are preferably different from the radicals generated in the generation space T2. The workpiece WP is processed by the radicals generated in the generation space T2 and the processing space S.

The resonator array structures 400 and 500 may be arranged on grid plates provided at substantially the same positions as the support members 422 and 522, instead of the support members 422 and 522. In this case, the second processing gas and the third processing gas may be supplied to the generation space T2 and the processing space S via the grid plates, respectively. Each grid plate may be made of, for example, a metal or a dielectric material.

In this way, in Modification 4, the processing gas is decomposed with different kinds of plasma energy in the generation space T2 and the processing space S, so that radicals can be generated and controlled as desired. Furthermore, by setting the resonant frequencies of the resonators in the resonator array structures 400 and 500 and the output frequencies of the corresponding RF power supplies 216a to different frequencies, radicals can be generated in multiple stages, thereby increasing the radical density. The number of stages in the resonator array structure is not limited to two, and any number of stages may be used.

Examples of the plasma processing in Modifications 3 and 4 include nitriding, oxidation, oxynitriding, hydrogen radical processing, oxygen radical processing, and hydrogen-oxygen radical processing. Additional examples of the plasma processing include PEALD (Plasma Enhanced Atomic Layer Deposition) film formation processing (precursor adsorption and nitriding or oxidation), PECVD (Plasma Enhanced Chemical Vapor Deposition) film formation processing, etc.

In the first embodiment described above, the resonator array structure 100 is described as including a plurality of resonators 101 arranged in a lattice pattern. However, the present disclosure is not limited thereto. For example, the resonator array structure may be formed by combining a plurality of rectangular resonators in which a plurality of resonators 101 in the X-axis direction or the Y-axis direction are integrated.

Furthermore, the above-described embodiments and modifications may be combined as appropriate within the scope of the present disclosure without causing any contradiction in content. For example, the resonator array structure 100 of the first embodiment may be used in place of the resonator array structures 300, 400 and 500 of Modifications 3 and 4.

According to each of the above-described embodiments, the plasma processing apparatus (plasma processing apparatus 1 or 201) includes a processing container (processing container 12 or 212), a substrate holder (stage 14), a gas supply (gas supply 38 or 238), an electromagnetic wave generator (microwave output device 16, or RF power supply 216), an electromagnetic wave supply (antenna 18 or 230), and a showerhead (resonator array structure 100 or 300). The processing container includes a processing chamber (processing space S) that provides a processing space for a substrate (workpiece WP), and a reaction chamber (generation space T) that provides a space for generating plasma. The substrate holder is configured to hold a substrate within the processing chamber. The gas supply is configured to supply a processing gas into the reaction chamber. The electromagnetic wave generator is configured to generate electromagnetic waves for plasma excitation that are supplied into the reaction chamber. The electromagnetic wave supply is configured to supply the electromagnetic waves into the reaction chamber. The showerhead partitions the processing chamber and the reaction chamber. The showerhead is configured to include a resonator array structure (resonator array structure 100 or 300) including a plurality of resonators (resonators 101 or 301) capable of resonating with the magnetic field component of the electromagnetic waves, having a size smaller than the wavelength of the electromagnetic waves, and arranged in the direction of the same plane, and through-holes (through holes 125 or 308) configured to bring the processing chamber into communication with the reaction chamber. The showerhead supplies radicals contained in the plasma generated in the reaction chamber to the processing chamber through the through-holes. As a result, high-density radicals can be generated.

Furthermore, according to each embodiment, the plurality of resonators have a structure in which a C-shaped ring member (ring member 111 or 311) made of a conductor is stacked on a dielectric body (dielectric body 112 or 312). As a result, it is possible to excite plasma.

Furthermore, according to the first embodiment, each of the plurality of resonators 101 is formed in a card shape for each of a set of two or more C-shaped ring members 111. The plurality of card-shaped resonators 101 are formed in the direction of the plane perpendicular to the partitioning direction surface of the showerhead. As a result, the plurality of resonators 101 can resonate with respect to the magnetic field H that is supplied from the antenna 18 and distributed in the rotation direction relative to the Z axis.

Furthermore, according to the first embodiment, each of the plurality of resonators 101 includes a set of two or more C-shaped ring members 111. Multiple sets of two or more C-shaped ring members 111 are connected to form a rectangular shape. The plurality of resonators 101 having the rectangular shape are formed in the direction of the plane perpendicular to the partitioning direction surface of the showerhead. As a result, the plurality of resonators 101 can resonate with the magnetic field H that is supplied from the antenna 18 and distributed in the rotation direction relative to the Z axis.

Furthermore, according to the second embodiment, each of the plurality of resonators 301 includes a set of two or more C-shaped ring members 311. The plurality of resonators 301 are formed in the direction of the plane parallel to the partitioning direction surface of the showerhead. As a result, the plurality of resonators 301 can resonate with the Z-axis magnetic field H supplied from the antenna 230.

Furthermore, according to each embodiment, the electromagnetic wave supply supplies a magnetic field component perpendicular to the direction of the plane on which the plurality of resonators are arranged. As a result, it is possible to excite plasma in the resonator array structure.

Furthermore, according to each embodiment, the showerhead includes a temperature control function (heater 126 or 314). As a result, it is possible to perform temperature control for the resonator array structure that also serves as a showerhead.

Furthermore, according to each embodiment, the processing container includes a plurality of reaction chambers (generation spaces T1 or T2). The electromagnetic wave generator (RF power supply 216a) supplies electromagnetic waves having different frequencies to each of the plurality of reaction chambers. As a result, the density of radicals can be increased.

Furthermore, according to each embodiment, the showerhead is arranged so that the surface thereof on the processing chamber side faces the substrate holding surface (electrostatic chuck 14c) of the substrate holder. The plasma processing apparatus further includes a drive mechanism capable of changing the distance between the processing chamber side surface of the showerhead and the substrate holding surface. As a result, the density of radicals that come into contact with the workpiece WP can be controlled.

Furthermore, according to each embodiment, the drive mechanism moves the substrate holder up and down. As a result, it is possible to increase the density of radicals that come into contact with the workpiece WP.

Furthermore, according to each embodiment, the drive mechanism moves the showerhead up and down. As a result, it is possible to control the density of radicals that come into contact with the workpiece WP.

Furthermore, according to each embodiment, the showerhead adjusts the conductance between the reaction chamber and the processing chamber so that the pressure in the reaction chamber is higher than the pressure in the processing chamber. As a result, it is possible to control the number of radicals generated in the reaction chamber and supplied to the processing chamber.

The embodiments disclosed herein should be considered to be exemplary and not limitative in all respects. Various omissions, substitutions, and modifications may be made to the above-described embodiments without departing from the spirit and scope of the appended claims.

In the first embodiment, for example, the cell-type resonator array structure 100 has been described as being formed by arranging the plurality of resonators 101 and the like, which can resonate with the magnetic field component of electromagnetic wave and have a size smaller than the wavelength of the electromagnetic wave, in a lattice pattern on the base plate 120. However, the arrangement of the plurality of resonators 101, and the like may be any arrangement along the plane of the base plate 120. For example, the plurality of resonators 101 may be arranged at predetermined intervals along one direction. In addition, for example, the plurality of resonators 101 may be arranged radially from the center of the base plate 120 (radial metamaterial).

Furthermore, in each of the above-described embodiments, a monopole antenna and an inductively coupled coil are used as antennas that input electromagnetic waves. However, the present disclosure is not limited thereto as long as a magnetic field can be generated in such a direction as to penetrate the ring members 111 of the plurality of resonators 101 of the resonator array structure 100. The antenna that inputs such electromagnetic waves is not limited to the monopole antenna and the inductively coupled coil. Any antenna or mechanism that inputs electromagnetic waves, such as a slot antenna, a capacitively coupled electrode, or a magnetron, may be used.

The present disclosure provides some embodiments of a plasma processing apparatus and showerhead capable of generating high-density radicals.

The present disclosure may also be configured as follows.
(1) A plasma processing apparatus, comprising:
   a processing container configured to include a processing chamber for providing a space in which a substrate is processed and a reaction chamber for providing a space in which plasma is generated;
   a substrate holder configured to hold the substrate within the processing chamber;
   a gas supply configured to supply a processing gas into the reaction chamber;
   an electromagnetic wave generator configured to generate an electromagnetic wave for plasma excitation to be supplied into the reaction chamber;
   an electromagnetic wave supply configured to supply the electromagnetic wave into the reaction chamber; and
   a showerhead configured to partition the processing chamber and the reaction chamber and to include a resonator array structure and through-holes configured to bring the processing chamber into communication with the reaction chamber, the resonator array structure including a plurality of resonators capable of resonating with a magnetic field component of the electromagnetic wave, the plurality of resonators having a size smaller than the wavelength of the electromagnetic wave and arranged in a direction of the same plane, and
   wherein the showerhead supplies radicals contained in the plasma generated in the reaction chamber to the processing chamber through the through-holes.
(2) The plasma processing apparatus of (1), wherein the plurality of resonators have a structure in which C-shaped ring members made of a conductor are stacked on a dielectric body.
(3) The plasma processing apparatus of (2), wherein each of the plurality of resonators is formed in a card shape for each set of two or more C-shaped ring members, and
   the plurality of resonators having the card shape are formed in a direction of the plane perpendicular to a partitioning direction surface of the showerhead.
(4) The plasma processing apparatus of (2), wherein each of the plurality of resonators includes a set of two or more C-shaped ring members,
   the plurality of resonators are formed in a rectangular shape by connecting a plurality of sets of the two or more C-shaped ring members, and
   the plurality of resonators having the rectangular shape are formed in a direction of the plane perpendicular to a partitioning direction surface of the showerhead.
(5) The plasma processing apparatus of (2), wherein each of the plurality of resonators includes a set of two or more C-shaped ring members, and
   the plurality of resonators are formed in a direction of the plane parallel to a partitioning direction surface of the showerhead.
(6) The plasma processing apparatus of any one of (1) to (5), wherein the electromagnetic wave supply supplies a magnetic field component perpendicular to a direction of the plane on which the plurality of resonators are arranged.
(7) The plasma processing apparatus of any one of (1) to (6), wherein the showerhead has a temperature control function.
(8) The plasma processing apparatus of any one of (1) to (7), wherein the processing container includes a plurality of reaction chambers, and
   the electromagnetic wave generator supplies electromagnetic waves of different frequencies respectively corresponding to the plurality of reaction chambers.
(9) The plasma processing apparatus of any one of (1) to (8), wherein the showerhead is arranged so that a processing chamber side surface thereof faces a substrate holding surface of the substrate holder, and further comprising:
   a drive mechanism capable of changing the distance between the processing chamber side surface of the showerhead and the substrate holding surface.
(10) The plasma processing apparatus of (9), wherein the drive mechanism moves the substrate holder up and down.
(11) The plasma processing apparatus of (9), wherein the drive mechanism moves the showerhead up and down.
(12) The plasma processing apparatus of any one of (1) to (11), wherein the showerhead adjusts the conductance between the processing chamber and the reaction chamber so that the pressure in the reaction chamber is higher than the pressure in the processing chamber.
(13) A showerhead, comprising:
   a resonator array structure including a plurality of resonators capable of resonating with a magnetic field component of an electromagnetic wave for plasma excitation, the plurality of resonators having a size smaller than the wavelength of the electromagnetic wave and arranged in a direction of the same plane; and
   through-holes configured to bring a processing chamber for providing a space in which a substrate is processed into communication with a reaction chamber for providing a space in which plasma is generated by the electromagnetic wave,
   wherein the showerhead is configured to partition the processing chamber and the reaction chamber and to supply radicals contained in the plasma generated in the reaction chamber to the processing chamber through the through-holes.
(14) The showerhead of (13), wherein the plurality of resonators have a structure in which C-shaped ring members made of a conductor are stacked on a dielectric body.
(15) The showerhead of (14), wherein each of the plurality of resonators is formed in a card shape for each set of two or more C-shaped ring members, and the plurality of resonators having the card shape are formed in a direction of the plane perpendicular to a partitioning direction surface of the showerhead.
(16) The showerhead of (14), wherein each of the plurality of resonators includes a set of two or more C-shaped ring members,
   the plurality of resonators are formed in a rectangular shape by connecting a plurality of sets of the two or more C-shaped ring members, and
   the plurality of resonators having the rectangular shape are formed in a direction of the plane perpendicular to a partitioning direction surface of the showerhead.
(17) The showerhead of (14), wherein each of the plurality of resonators includes a set of two or more C-shaped ring members, and
   the plurality of resonators are formed in a direction of the plane parallel to a partitioning direction surface of the showerhead.
(18) The showerhead of any one of (13) to (17), which has a temperature control function.

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

What is claimed is:

1. A plasma processing apparatus, comprising:
a processing container configured to include a processing chamber for providing a space in which a substrate is processed and a reaction chamber for providing a space in which plasma is generated;
a substrate holder configured to hold the substrate within the processing chamber;
a gas supply configured to supply a processing gas into the reaction chamber;
an electromagnetic wave generator configured to generate an electromagnetic wave for plasma excitation to be supplied into the reaction chamber;
an electromagnetic wave supply configured to supply the electromagnetic wave into the reaction chamber; and
a showerhead configured to partition the processing chamber and the reaction chamber and to include a resonator array structure and through-holes configured to bring the processing chamber into communication with the reaction chamber, the resonator array structure including a plurality of resonators capable of resonating with a magnetic field component of the electromagnetic wave, the plurality of resonators having a size smaller than the wavelength of the electromagnetic wave and arranged in a direction of the same plane, and
wherein the showerhead supplies radicals contained in the plasma generated in the reaction chamber to the processing chamber through the through-holes.

2. The plasma processing apparatus of claim 1, wherein the plurality of resonators have a structure in which C-shaped ring members made of a conductor are stacked on a dielectric body.

3. The plasma processing apparatus of claim 2, wherein each of the plurality of resonators is formed in a card shape for each set of two or more C-shaped ring members, and
the plurality of resonators having the card shape are formed in a direction of the plane perpendicular to a partitioning direction surface of the showerhead.

4. The plasma processing apparatus of 2, wherein each of the plurality of resonators includes a set of two or more C-shaped ring members,
the plurality of resonators are formed in a rectangular shape by connecting a plurality of sets of the two or more C-shaped ring members, and
the plurality of resonators having the rectangular shape are formed in a direction of the plane perpendicular to a partitioning direction surface of the showerhead.

5. The plasma processing apparatus of 2, wherein each of the plurality of resonators includes a set of two or more C-shaped ring members, and
the plurality of resonators are formed in a direction of the plane parallel to a partitioning direction surface of the showerhead.

6. The plasma processing apparatus of claim 1, wherein the electromagnetic wave supply supplies a magnetic field component perpendicular to a direction of the plane on which the plurality of resonators are arranged.

7. The plasma processing apparatus of claim 1, wherein the showerhead has a temperature control function.

8. The plasma processing apparatus of claim 1, wherein the processing container includes a plurality of reaction chambers, and
the electromagnetic wave generator supplies electromagnetic waves of different frequencies respectively corresponding to the plurality of reaction chambers.

9. The plasma processing apparatus of claim 1, wherein the showerhead is arranged so that a processing chamber side surface thereof faces a substrate holding surface of the substrate holder, and further comprising:
a drive mechanism capable of changing the distance between the processing chamber side surface of the showerhead and the substrate holding surface.

10. The plasma processing apparatus of claim 9, wherein the drive mechanism moves the substrate holder up and down.

11. The plasma processing apparatus of claim 9, wherein the drive mechanism moves the showerhead up and down.

12. The plasma processing apparatus of claim 1, wherein the showerhead adjusts the conductance between the processing chamber and the reaction chamber so that the pressure in the reaction chamber is higher than the pressure in the processing chamber.

13. A showerhead, comprising:
a resonator array structure including a plurality of resonators capable of resonating with a magnetic field component of an electromagnetic wave for plasma excitation, the plurality of resonators having a size smaller than the wavelength of the electromagnetic wave and arranged in a direction of the same plane; and
through-holes configured to bring a processing chamber for providing a space in which a substrate is processed into communication with a reaction chamber for providing a space in which plasma is generated by the electromagnetic wave,
wherein the showerhead is configured to partition the processing chamber and the reaction chamber and to supply radicals contained in the plasma generated in the reaction chamber to the processing chamber through the through-holes.

14. The showerhead of claim 13, wherein the plurality of resonators have a structure in which C-shaped ring members made of a conductor are stacked on a dielectric body.

15. The showerhead of claim 14, wherein each of the plurality of resonators is formed in a card shape for each set of two or more C-shaped ring members, and
the plurality of resonators having the card shape are formed in a direction of the plane perpendicular to a partitioning direction surface of the showerhead.

16. The showerhead of claim 14, wherein each of the plurality of resonators includes a set of two or more C-shaped ring members,
the plurality of resonators are formed in a rectangular shape by connecting a plurality of sets of the two or more C-shaped ring members, and
the plurality of resonators having the rectangular shape are formed in a direction of the plane perpendicular to a partitioning direction surface of the showerhead.

17. The showerhead of claim 14, wherein each of the plurality of resonators includes a set of two or more C-shaped ring members, and
the plurality of resonators are formed in a direction of the plane parallel to a partitioning direction surface of the showerhead.

18. The showerhead of claim 13, which has a temperature control function.
